(19) United States
(12) Patent Application Publication
(10) Pub. No.: US 2011/0298352 A1
(43) Pub. Date: Dec. 8, 2011

(54) LED LAMP AND METHODS OF MANUFACTURING THE SAME

(76) Inventor: Pannirselvam A/L Velu, Penang (MY)

(21) Appl. No.: 13/152,701

(22) Filed: Jun. 3, 2011

(30) Foreign Application Priority Data
Jun. 7, 2010 (MY) PI 2010002624

(51) Int. Cl. H01J 7/24; H05K 3/30; H01J 5/48

(52) U.S. Cl. 313/46; 313/318.01; 29/832

(57) ABSTRACT

A light emitting diode (LED) lamp includes one or more light emitting diodes (LEDs). The one or more LEDs are mounted directly on a metallic base and a circuit associated with the one or more LEDs is embedded in the metallic base. The metallic base is copper, aluminium, or a thermally conductive material that is plated with a metallic plating. The metallic base is attached directly, by metal-to-metal contact, to a metallic heat sink. The one or more LEDs, the metallic base and the heat sink, are disposed inside a housing.

### PRIORITY

This application claims priority under 35 U.S.C. §119(a) to an application entitled “A HIGH THERMAL EFFICIENCY LED LAMP AND METHOD OF MANUFACTURING THE SAME” filed in the Malaysia Intellectual Property Office on Jun. 7, 2010 and assigned Application No. PI 2010002624, the contents of which are incorporated herein by reference.

### BACKGROUND OF THE INVENTION

Light Emitting Diode (LED) lamp technology is an emerging new industry expected to be the most widely accepted source of illumination globally in the very near future.

FIG. 1 outlines several stages in the process of manufacturing an LED lamp. The present invention relates to Phase 3 of that process and, in particular, to a LED lamp or bulb, and to a method of mounting and connecting the LED light engine or LED package while maximizing the thermal efficiencies to ensure high levels of light output.

Presently there are several types of LED lamps available. Several inherent properties with the design of such lamps, as well as the manufacturing technologies used, limit the maximum power that can be handled by these lamps. Typical current LED lamps manufactured as replacements for incandescent lamps are rated at up to 12 Watt power inputs. The current designs do not seem to be able to handle more than this 12 Watt power input and as such are not widely acceptable for general illumination. The poor thermal management inherent in the designs of the lamps exacerbates poor light output.

While generating light, LEDs produce heat which needs to be efficiently removed. Poor heat removal will result in excessive junction temperatures and degradation of light output leading to shorter life span of the product. To enable heat removal, current LED lamp manufacturers mount LEDs onto metal core printed circuit boards (MCPCBs) or ceramic based substrates which are mounted onto heat sink bodies made of aluminium castings or aluminium extrusions. The manufacture of prior art LED lamps of this kind limits the maximum power handling capacity of the lamps, which is typically reported to be not more than 12 Watts with a shorter LED life span than typical. An implication of existing design constraints is the lamp's inability to effectively transfer heat from each LED, sometimes known as the LED light engine or LED package, to the ambient air.

FIG. 2 illustrates the thermal flow path from a LED “L” to a printed circuit board or PCB “P” to a heat sink “S” and finally to ambient air “A”.

Thermal resistance should be kept as low as possible from the LED package to the heat sink (which is commonly made of aluminium casting). However, the thermal resistance within currently available LED lamp designs remains high, resulting in inefficient thermal transfer as will be explained below. In summary, low light outputs result from inefficient thermal transfer from the LED light engine, through the heat sink, and dissipation of heat through thermal radiation to the atmosphere. Potential reasons for this are summarised as follows:

### 1. Limitations Due to Aluminium Castings

### Thermal Conductivity

FIG. 3 compares the thermal conductivities of some materials, including some that are typically used in heat sinks. The thermal conductivity of aluminium castings are about 50% that of extruded aluminium. A larger thermal conductivity would require a larger surface area on an LED lamp for effective thermal transfer, but most existing LED lamps are manufactured using cast aluminium with limited surface area. The reasons for the limited surface areas are:

(a) Aesthetics:
The manufacturer tries to make LED lamps that are compatible with existing lamp fittings and that imitate the size and shape of the current incandescent lamps and compact fluorescent lamps (CFLs); and

(b) Casting Limitations:
Casting processes impose limitations on minimum fin thickness and maximum fin heights.
   Number of Fins Vs. Surface Area

The casting process imposes significant constraints on the maximization of the number of fins on a casting. Casting requires a high draft angle for mould releasability resulting in a typical minimum thickness of fin being no less than 0.9 mm. The draft angle requirement means that there is a trade off between fin height and the number of fins. If fin height is increased in an attempt to increase surface area, the number of fins will need to be reduced if the heat sink is of similar size. More fins will obviously mean more surface area which could result in more efficient thermal transfer but constraints of the casting processes prevent the number of fins being increased beyond a certain number.

FIG. 4 illustrates a fin quantity optimization graph in which the maximum fin temperature is plotted against the number of same height fins on a given base area. Too many fins or too few fins will each adversely affect thermal transfer and increase the fin temperature. More fins are possible if the fins are shortened but the surface area contributed by each fin will be reduced. There is always a trade off. In practice, either the fins must be shallow to allow for more fins or more widely spaced to allow for taller fins. The thermal modelling illustrated by FIG. 4 shows changes in performance with changes in the number of fins. It is apparent that there is an ideal number of fins within a lamp form factor to optimise power handling capacity. Increasing the number of fins beyond a certain maximum will also restrict air space between the fins which could result in blocked air flows, which could lead to increased temperatures and thermal inefficiencies.

### Emissivity Limitations

In all existing LED lamp designs, the transfer of thermal energy from heat sink to ambient air relies mostly on thermal radiation. In these designs, emissivity factors play a key role, while convection by air flow will be inefficient because the designs do not allow for induced or forced air circulation.

FIG. 5 shows emissivity values of some common materials. Aluminium has very low emissivity values. This makes thermal transfer from a LED in a LED lamp to the ambient more inefficient. This further confirms that an aluminium casting process might not be the optimum approach to manufacturing LED lamps.

In summary, existing LED lamps have several limitations caused predominantly by the casting process used in the manufacture of the heat sink. Aluminium castings have a lower thermal conductivity (typically 50% of extruded aluminium), very poor emissivity through radiation, poor heat transfer through convection due to inefficient air flow, and insufficient surface area because of non optimal fin design imposed by difficulties manufacturing a LED lamp having a lamp form factor that is close to that of the current incandescent or compact fluorescent bulbs.

While the above mainly outlines the causes of ineffectiveness of heat transfer from heat sink to the heat sink surface (material related—inferior properties of aluminium castings) and from the heat sink surface to the surrounding air (emissivity and convective inefficiencies), another factor contributing to limitations in achieving higher light output is in the management of heat flow from the LED itself to heat sink. This is discussed below.

2. Thermal Resistance from LED Package to the Heat Sink

FIG. 6 shows a simplified typical arrangement of a LED in existing LED Lamps.

FIG. 7 illustrates the LED lamp interfaces through which heat energy travels. The interfaces, X, Y and Z, are inherent in typical designs of current LED lamps. In general, the more interfaces that are incorporated within a design, the higher is the resulting overall thermal resistance, leading to inefficient thermal management.

The interfaces X and Y are inherent in most of the LED lamps currently produced. Solder or silver epoxy is used at interface X, resulting in thermal conductivities of 50 W/mK and 2 W/mK respectively, while interface Y will typically be a thermal interface material with a thermal conductivity of about 2-10 W/mK.

A third disruptive thermal resistance is embedded within the substrate material Z. Currently, LED lamp manufacturers will use MCPCBs or ceramic substrates. Metal core PCBs have a layer of isolating material which increases the thermal resistance and the thermal conductivity of the ceramic material is always poor.

It is therefore an object of the present invention to provide a LED lamp, and a method of manufacturing a LED lamp, which overcomes at least one of the aforementioned problems, or at least provides the public with a useful alternative.

### SUMMARY OF THE INVENTION

In a first aspect the invention may be broadly said to be a light emitting diode (LED) lamp comprising one or more light emitting diodes (LEDs) mounted directly on a metallic base, wherein a circuit associated with the LED or LEDs is embedded in the metallic base.

Preferably, the metallic base is copper, aluminium, or a thermally conductive material that is plated with a metallic plating. The metallic plating is preferably gold, silver, or tin.

The metallic base is preferably attached directly, by metal-to-metal contact, to a metallic heat sink. Preferably the LED or LEDs, the metallic base and the heat sink, are disposed inside a housing. The housing is preferably made of glass, aluminium, steel, or a plastics material.

Preferably, the LED lamp has a longitudinal axis and the heat sink comprises longitudinally extending heat dissipating fins that are radially disposed about the longitudinal axis. Preferably, the heat sink comprises a

metallic sub-base which is attached to the metallic base, each fin projects outwardly away from the longitudinal axis, each fin is shaped substantially correspondingly with an internal shape of the housing, and each fin includes a laterally-extending foot that is attached to the metallic sub-base. Preferably, the sub-base includes a central region, an outer annular region, and a plurality of radial tabs that are each integral with and extend from an outer perimeter of the outer annular region, the central region and the outer annular region are coaxial with the longitudinal axis, the metallic base is attached directly to the central region by metal-to-metal contact, and each tab is folded radially inward towards the longitudinal axis to respectively engage the foot of one of the fins between the tab and the outer annular region. Each foot is preferably engaged between the respective tab and the outer annular region of the sub-base by swaging, resistive welding, ultrasonic welding, soldering, spot welding, screwing or riveting.

Preferably, the housing includes an air inlet and an air outlet, and, in use of the LED lamp, the air inlet is located at a lower region of the housing, the air outlet is located at an upper region of the housing, and the heat sink is exposed to air which enters the housing through the air inlet to be heated by the heat sink, causing the air to rise inside the housing and be expelled from the housing through the air outlet, thereby drawing cooler air into the housing through the air inlet. Preferably, the housing comprises a body portion which substantially surrounds the heat sink fins and an optically transparent or translucent portion, and the air inlet is defined by a gap between the body portion and the optically transparent or translucent portion.

In a second aspect the invention may be broadly said to be a method of manufacturing a light emitting diode (LED) lamp comprising the steps of mounting one or more light emitting diodes (LEDs) directly on a metallic base, and embedding a circuit associated with the LED or LEDs in the metallic base.

Preferably, the metallic base is copper, aluminium, or a thermally conductive material plated with a metallic plating. The metallic plating is preferably gold, silver, or tin.

Preferably, the method of the second aspect further comprises the step of attaching the metallic base to a metallic heat sink by direct metal-to-metal contact. The method of the second aspect may still further comprise the steps of providing the heat sink with a plurality of radially-disposed heat dissipating fins which extend outwardly away from a longitudinal axis of the LED lamp; attaching the fins by direct metal-to-metal contact to a metallic sub-base; attaching the metallic sub-base to the metallic base; and housing the fins, the metallic sub-base and the metallic base inside a housing.

Preferably, the step of attaching the fins by direct metal-to-metal contact to the metallic sub-base is performed by swaging, resistive welding, ultrasonic welding, soldering or spot welding, or by use of one or more fasteners.

Preferably, the step of attaching the metallic sub-base to the metallic base, is performed by swaging, resistive welding, ultrasonic welding, soldering or spot welding, or by use of one or more fasteners.

Preferably, the step of mounting the one or more LEDs directly on the metallic base is performed by a soldering process or by using an electrically-conductive adhesive or a thermally-conductive adhesive. Preferably, the adhesive is an epoxy.

In a third aspect the invention may be broadly said to be a light emitting diode (LED) lamp manufactured in accordance with the steps of the second aspect as defined above.

### BRIEF DESCRIPTION OF THE DRAWING FIGURES

The accompanying drawings, which are incorporated in and constitute a part of this specification, illustrate a preferred implementation of the invention and, together with the description, serve to explain the advantages and principles of the invention. In the drawings:

FIG. 1 illustrates a schematic diagram of a process for producing a LED lamp;

FIG. 2 illustrates a thermal flow path diagram;

FIG. 3 illustrates a thermal conductivity graph for various heat sink materials;

FIG. 4 illustrates a maximum temperature vs. fin quantity graph;

FIG. 5 illustrates a table of common material emissivity;

FIG. 6 illustrates a model of a prior art LED lamp;

FIG. 7 illustrates a thermal flow path regime in a prior art LED lamp;

FIG. 8 illustrates an improved thermal flow path regime in a LED lamp in accordance with the present invention;

FIG. 9 illustrates schematically the direct metal-to-metal contact which occurs between a LED device and a heat sink fin in accordance with the present invention;

FIG. 10 illustrates a front view of a LED lamp in accordance with a preferred embodiment of the present invention;

FIG. 11 illustrates a cross sectional view of the LED lamp of FIG. 10 taken along a line which extends through the longitudinal axis of the lamp, and through radially opposed heat sink fin feet;

FIG. 12 illustrates a plan view of the underside of a LED mount showing LEDs and LED circuitry embedded in the LED mount;

FIG. 13 illustrates a plan view of the underside of a LED mount showing a LED array;

FIG. 14 illustrates a side view of the LED mount and LED array of FIG. 13;

FIG. 15 illustrates an enlarged cross sectional view of part of the LED lamp shown in FIGS. 10 and 11;

FIG. 16 illustrates an enlarged cross sectional view of the attachment between the LED sub-base and a foot associated with a heat sink fin, of the LED lamp shown in FIGS. 10 and 11;

FIG. 17 illustrates a cutaway perspective view of parts of the internal components of the LED lamp at a lower internal region thereof, including LEDs and a LED base mounted to a LED sub-base attached to heat sink fins;

FIG. 18 illustrates the cross sectional view of FIG. 11 indicating the path of air flow into a housing at an the air inlet, past heat sink fins, and out through an air outlet;

FIG. 19 illustrates a comparative performance chart between the LED lamp of the present invention and prior art lamps; and

FIG. 20 illustrates typical dimensions of one preferred embodiment of the LED lamps described with reference to FIGS. 10 to 19.

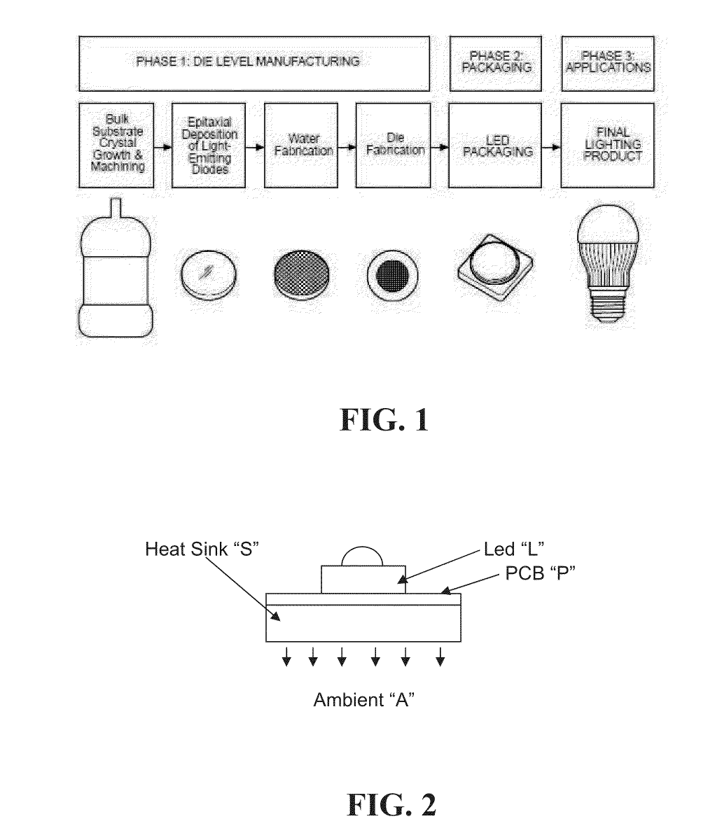

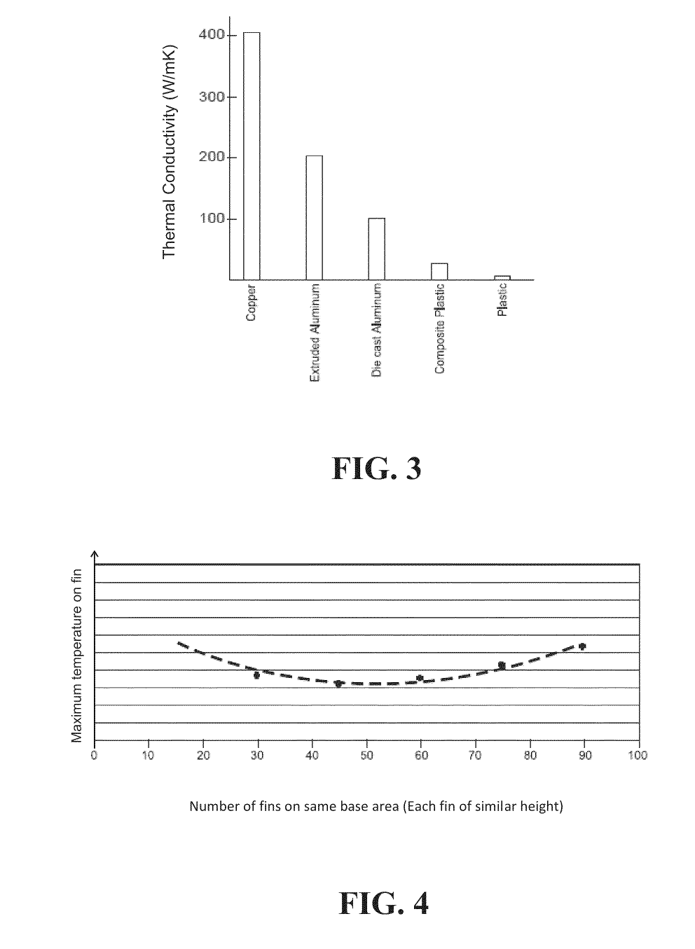

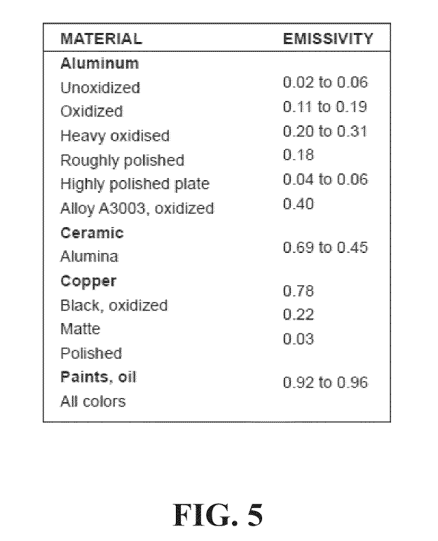

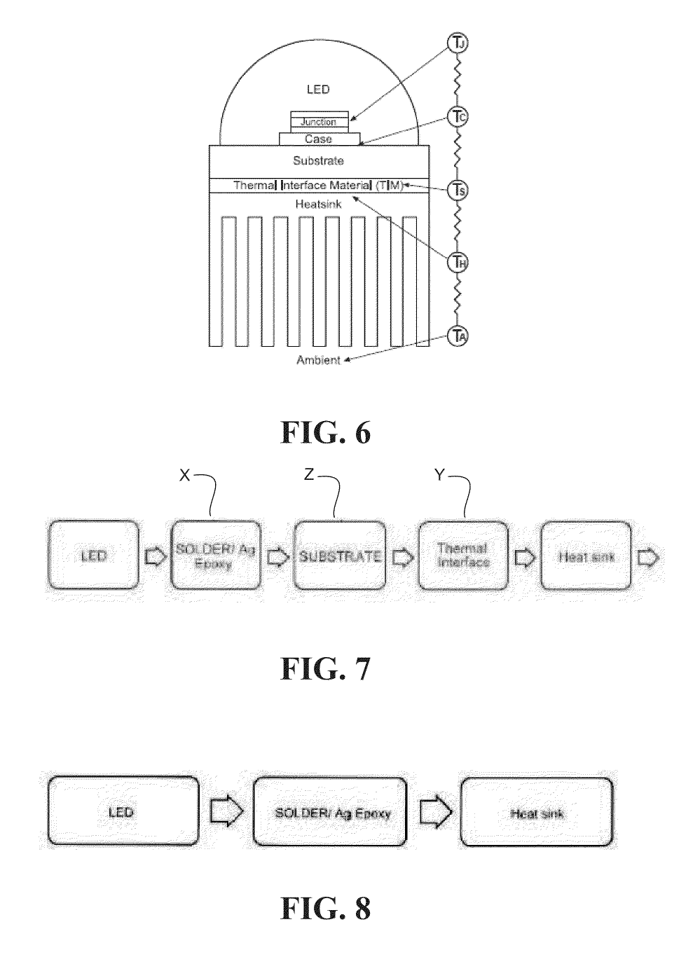

### DETAILED DESCRIPTION OF THE PREFERRED EMBODIMENTS

The following detailed description of the invention refers to the accompanying drawings. Although the description includes exemplary embodiments, other embodiments are possible, and changes may be made to the embodiments described without departing from the spirit and scope of the invention as defined in the accompanying claims. Wherever possible, the same reference numbers will be used throughout the drawings and the following description to refer to the same and like parts.

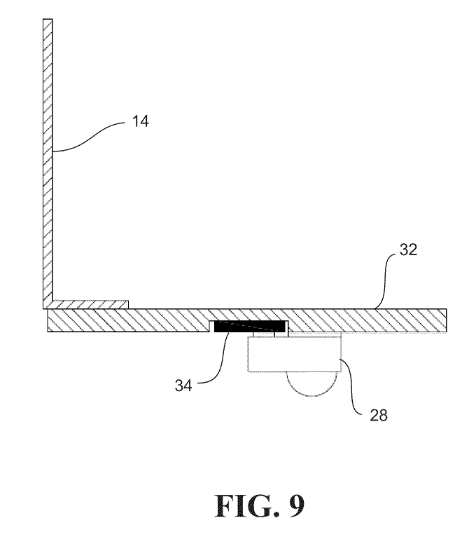

The present invention relates to a LED lamp or bulb 10 that has been developed to reduce the thermal management constraints that apply to prior art LED lamps of this type, thus allowing the lamp to handle a much higher wattage efficiently. The invention allows power input of at least 20 Watts with high light output. The key considerations in achieving the present invention have been an improved thermal transfer from the LED 28 to the heat sink 14 as shown in the model in FIG. 9, and thermal transfer from the surface of the heat sink 14 to the surrounding air through more effective thermal radiation and convective thermal transfer process.

FIG. 8 shows thermal resistances of a LED according to the present invention and the elimination of two of the three thermal resistance sections which exist in prior art LED lamps.

FIG. 9 is a schematic illustration showing principal features of the present invention. A LED 28 is mounted directly onto a LED mount or base 32 which is attached directly to a heat sink 14, thus achieving a low resistance thermal flow path in accordance with the present invention. Circuitry 34, which is connected to, or associated with, the LED 28, is embedded in a cavity in the LED mount or base 32.

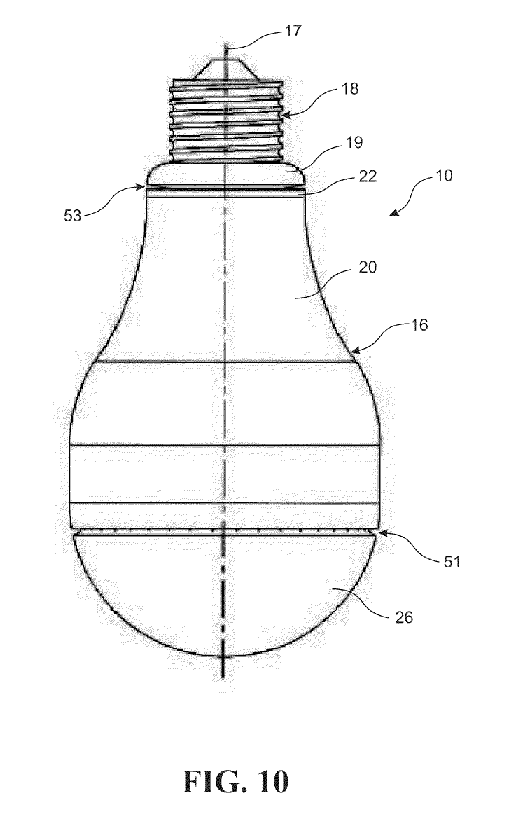

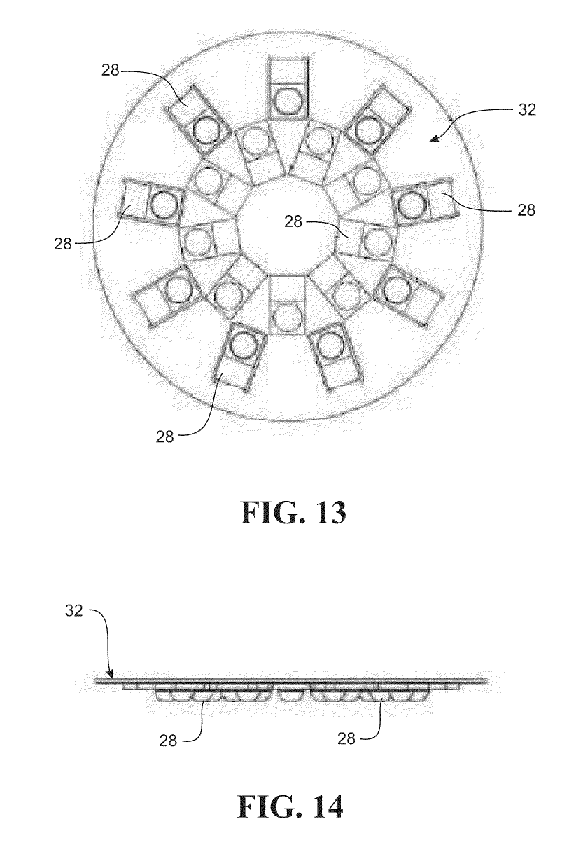

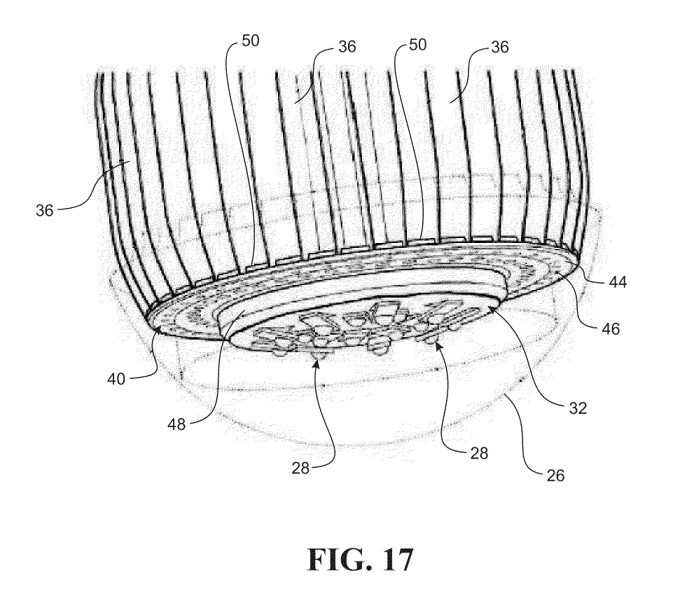

FIGS. 10 to 18 show a LED lamp with further features of the present invention, including an improved convective cooling process which causes an air flow to be induced inside a lamp casing or housing 16, as well as improvements in emissivity with increased thermal radiation efficiencies besides the thermal conductivity improvements.

FIGS. 10 to 18 show a LED lamp 10 according to a preferred embodiment of the present invention. The LED lamp has a longitudinal axis 17, shown in FIG. 10.

For convenience of this description of the LED lamp 10, references made herein to ‘upper’, ‘lower’, ‘top’, ‘bottom’, ‘above’, ‘below’, and the like, are to be understood as referring to the LED lamp when orientated as clearly shown in FIGS. 10, 11 and 18 with the axis 17 vertical and with a connecting cap 18 at the upper axial end of the lamp. Although the LED lamp is described herein in this orientation, the LED lamp can be operated in other orientations.

The LED lamp is primarily designed to operate in this vertical orientation, with the connecting cap uppermost. This orientation is common in typical installations where the lamp is fitted, often as a replacement for incandescent or compact fluorescent lamps. Typically, the lamp is fitted to a batten holder that is fixed to the ceiling surface, or the lamp is fitted to a lamp holder suspended by a connecting cable from a ceiling rose fixed to a ceiling.

FIG. 10 shows external features of the LED lamp 10 which includes a cap 18 at an upper end thereof. The cap is devised for engaging in a lamp socket (not shown) so that power can be supplied to the LED lamp 10. The cap 18 may be threaded or unthreaded, for example a bayonet connection, and includes a plug 19 to which a outer casing or housing 16 is attachable such that the outer casing projects longitudinally and downwardly therefrom.

The outer casing 16 is divided into two sections, an upper body section 20 including a flat base portion 22 located proximate the plug 19, and a lower body section being a domed optically transparent or translucent cover 26 for subsequent attachment as explained further below. The body section 20, apart from its base portion 22, forms the major outer wall of the lamp. The lower distal end of the body section 20 of the housing is of a larger diameter than that of the base portion 22.

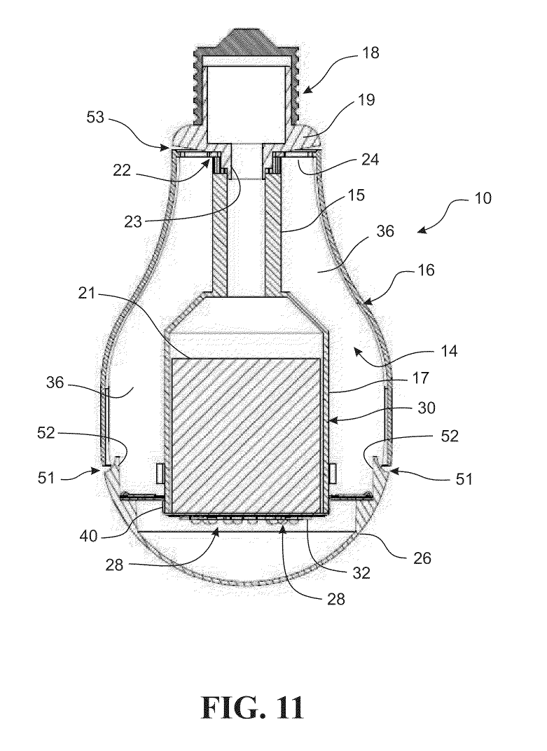

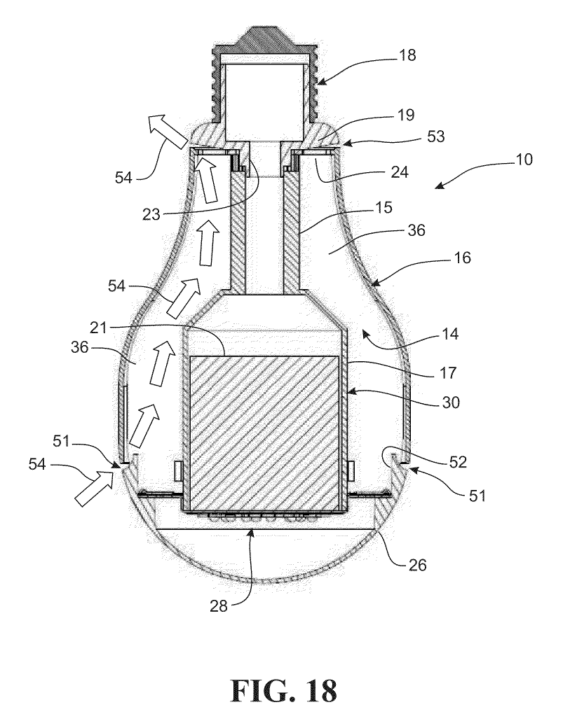

The upper body section 20 is attached to a spigot 23 which projects downwardly from the underside of the plug 19. An internal component 30, shown in the cross-sectional views of FIGS. 11 and 18, is also fixed to the spigot. The internal component has a relatively smaller diameter upper hollow neck portion 15 and a relatively larger diameter lower housing portion 17. The internal component is fixed by the upper end of its neck portion 15 to the spigot 23. This fixing may be used to retain the attachment of the upper body section 20 to the spigot.

Power supplied to the lamp 10 is transferred internally to the LED 28 or array of LEDs 28. The LEDs are protected within the cover 26. The cover 26 is preferably made of a plastics material. The number of LEDs used is dependent upon the power input and level of illumination required. The means by which electricity is supplied internally from the cap 18 to the LED or the array of LEDs is considered known in the art and will not be described. Such component 21, which may for example be a built-in power supply for the lamp 10, does not relevantly contribute to the present invention but can be housed inside the internal component 30.

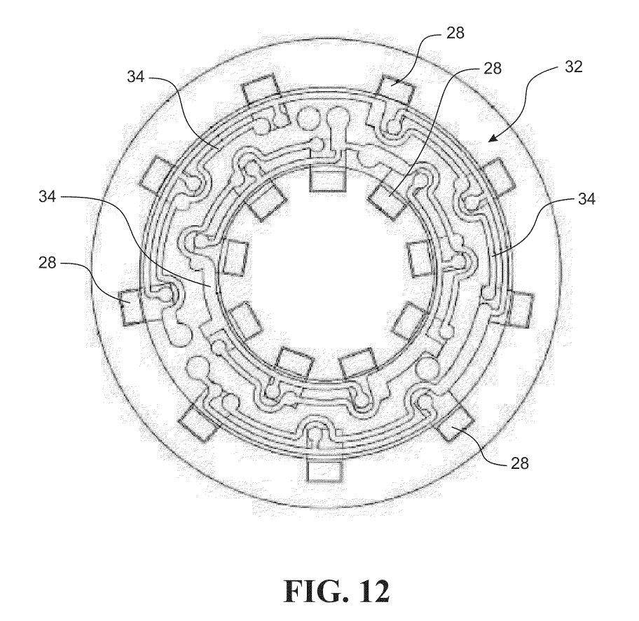

FIG. 12 illustrates a plan view of the underside of a LED base or mount 32. The LEDs 28 are mounted directly to the underside of the LED base or mount 32. Preferably, the semiconductor die or chip of each LED 28 is mounted directly to the LED mount 32 without any insulative interface between the LED mount 32 and at least one electrode of the LED. The LED mount 32 is metallic, preferably made of copper, aluminium, or a thermally conductive material that is plated with a metallic plating, and is preferably more than 0.12 mm thick. The metallic plating is preferably gold, silver, or tin. The LED circuitry 34 can be laid out on a suitable material such as a metal core printed circuit board (MCPCB), or a ceramic, for example FR4, printed circuit board, and is embedded into the LED mount 32. The circuitry 34 connects the LEDs of an array in series and parallel to balance currents and voltages between the individual LEDs. The present invention is not intended to be limited to any particular LED position, or arrangement or array of LEDs.

The semiconductor die or chip of each LED 28 is adapted to be mounted directly to the metallic LED base or mount 32 by any suitable method, including a soldering process or by attachment using any electrically and/or thermally conductive adhesive. The adhesive is preferably an epoxy.

The LED lamp 10 includes a heat sink 14 in the form of a plurality of radially disposed, heat radiating fins 36. Each fin extends from the internal component 30 radially outwardly, away from the longitudinal axis 17, to the body section 20 of the outer casing or housing 16, and longitudinally downward from the flat base portion 22 to approximately the LED mount base 32. Each fin 36 terminates at its lower end in a small perpendicular foot 38.

The upper end of each fin is located in a respective radial slot formed in the upper neck portion of the internal component 30. The foot 38 at lower end of each fin 36 is attached to a sub-base 40 as will be explained further below.

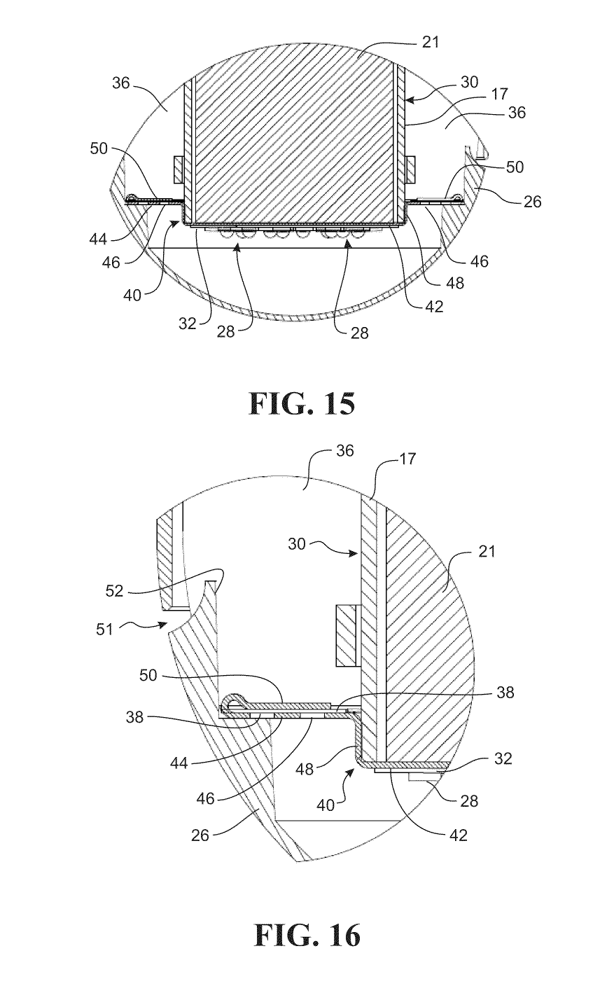

FIGS. 15, 16 and 17 illustrate in enlarged views the thermally conductive connection between the LEDs 28 and the fins 36. The LED mount 32, with the attached LEDs 28, is mounted to the sub-base 40. The sub-base 40 is a substantially circular structure that includes a central circular region 42 on which the LED mount 32 is attached, and an outer annular region 44. The LED mount 32 and sub-base 40 are pressed or swaged together, otherwise or connected together, for example by resistive welding, ultrasonic welding, soldering, spot welding, or by any conventional fasteners such as screws or rivets.

The sub-base 40 is located centrally at the lower larger diameter end of the internal component 30, with each perpendicular foot 38 of the fins 36 abutting against the upper surface of the outer annular region 44. This outer annular region 44 includes a plurality of apertures 46. The sub-base is made by a drawing process.

In the embodiment shown in FIGS. 11, 15, 16, 17 and 17, the fins 36 do not extend all the way down to the lower end of the internal component 30. In this case, the central circular region 42 and the outer region 44 are spaced apart longitudinally, and are joined by a cylindrical side wall 48 of the sub-base 40. The present invention is not intended to be limited to this particular sub-base design.

A plurality of flexible radial tabs 50 are circumferentially spaced around the perimeter of the outer annular region 44. Initially, each tab 50 extends radially outward from the perimeter of the annular region, and during manufacture of the LED lamp is folded over to extend between two adjacent fins and over the top of a fin foot 38. Thus, each fin foot 38 becomes wedged between a tab 50 and the upper face of the outer annular region 44 of the sub-base 40 there beneath. Pressure can be applied between the tabs 50 and the underlying annular region 44 to improve the thermal conduction of the interface between the feet of fins and the sub-base 40. The tabs 50 and feet 38 are preferably swaged together and to the annular outer region 44 of the sub-base 40. When sufficient swaging pressure is applied, portions of the feet and tabs ‘flow’ into the apertures 46 in the outer annular region 44, to strengthen the interface.

The sub-base 40 may be made of copper, aluminium or a thermally conductive material plated with gold, silver, and/or tin, for example. The fins may be attached to the sub-base by swaging, resistive welding, ultrasonic welding, soldering, spot welding, or by any conventional fasteners such as screws or rivets. Once attached, the three separate components, being the tab 50, the foot 38, and the sub-base 40, effectively behave as a unitary metal piece with the elimination of inefficient interfaces, resulting in higher thermal efficiency.

The heat sink fins 36, which may be stamped from a thin copper strip unwound from a coil, can be inserted, by a high-speed servo-driven mini-press, into slots in a plastic injection moulded core. For example, the fins may be inserted into respective radial slots in the cylindrical portions of the external wall of the internal component 30.

The domed optical cover 26 is attached by way of an interference-type engagement with the fins 36. Radial slots disposed around the open circular perimeter at the upper end of the cover 26 form inwardly curved fingers 52 there between. The lower outer edge of each heat sink fin 36 is received in a respective slot and engaged between a pair of adjacent fingers 52. The engagement is such that when the domed optical cover is pushed upwardly, the cover 26 remains locked to the fins 36 unless pried off.

A lower gap 51 between the upper body section 20 and the domed cover 26 of the outer casing 16 allows air to flow from the outside to the inside of the housing 16 of the LED lamp 10. The plug 19 is shaped to leave an upper gap 53 between the underside of the plug and the flat base portion 22 at the upper end of the upper body section 20. The respective gaps 51 and 53 at the lower and upper ends of the upper body section 20 allow air to flow in and out of the housing to create a self-induced air flow that cools the fins 36 through a convective process.

FIG. 18 shows an air flow path depicted by arrows 54. Relatively cool ambient air is sucked in through the opening between the lower end of the upper body section 20 and the upper end of the optical cover 26. As the temperature of the LEDs rises, the heat is transferred to the heat sink fins 36 via the LED mount 32 and sub-base 40. As the fins heat up, the air surrounding them will be heated. The heated air will rise inside the housing, drawing cooler air in through the opening between upper body section and cover of the outer casing 16. The heated air will be expelled out through apertures 24 in the base portion 22 and through the gap between the plug 19 and the base portion 22 of the upper body section. Over time this process will be stabilized ensuring a continuous flow of air past the fins ensuring an effective convective cooling process.

The skilled addressee would now realise the advantages of the present invention. The lamp 10 ensures that the thermal path from the LED or LEDs to ambient air has a low thermal resistance, and when combined with a convective cooling process, results in a high power handling capability with high thermal efficiency.

Fins 36 have a thickness of at least 0.05 mm, and are made out of black oxidised copper or black anodised aluminium, for example, to improve thermal efficiency further through a more effective thermal radiation.

Data regarding the performance of the LED lamp 10 has been collected and proves that this form of LED lamp is highly efficient compared to existing LED lamps and various other lamps available for general illumination.

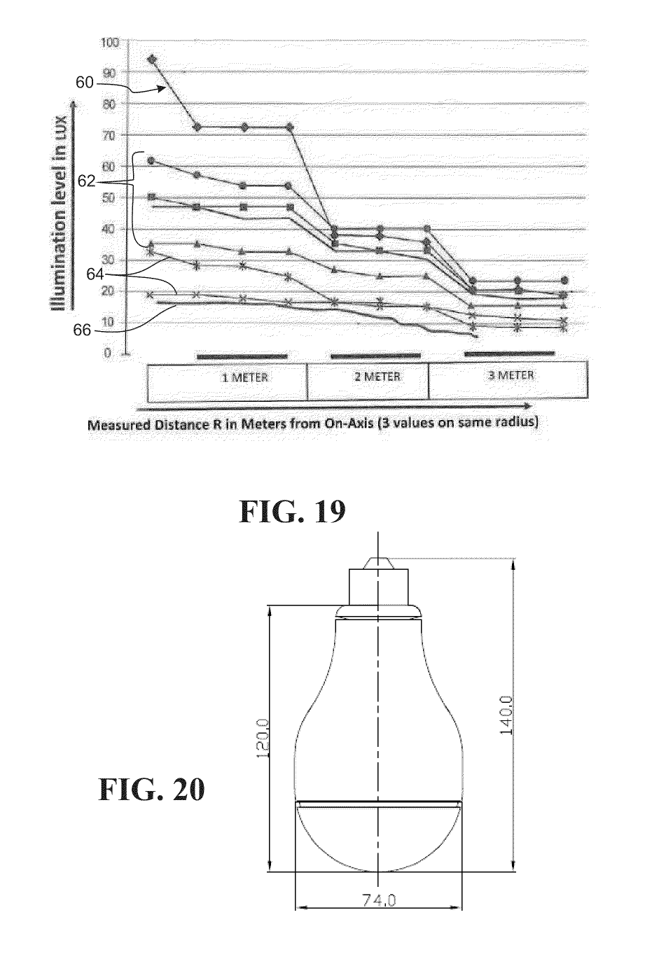

FIG. 19 illustrates comparative performances of various lamp types. Graph 60 represents an 18 W LED lamp of the present invention that well surpasses compact fluorescent lamps (CFLs) of various wattage (represented by graphs 62), incandescent lamps of various wattage (represented by graphs 64), and a prior art LED lamp (represented by graph 66).

FIG. 20 illustrates typical dimensions of one preferred embodiment of the LED lamps described above with reference to FIGS. 10 to 19. The form factor and dimensions of this lamp make it suitable for fitting into standard light fittings as a replacement for incandescent or compact fluorescent lamps. As shown in FIG. 20, the overall length is 140 mm and the maximum diameter is about 74 mm. This LED lamp successfully handled 18 Watts with an average LED temperature of about 98° C. which compares favourably with the LED manufacturer's rated maximum allowable LED temperature of 125° C. Light output, i.e. luminance, was tested continuously using a light meter. There was no change in light output after the first 15 minutes. These test results indicate that this LED lamp could handle up to 25 Watts.

In summary, at least some embodiments of the LED lamp 10 of the present invention, and its method of manufacture, provide a number of distinct advantages over existing LED lamps in the market, including but not limited to:
the self induced air flow which increases convective efficiencies and is facilitated by use of an external casing or housing, e.g. made of either plastic, glass, aluminium or steel;
the mounting of LEDs directly onto a metallic substrate (e.g. made of copper) which in turn is firmly bonded to heat sink fins, resulting in high thermal efficiencies;
the use of fins of black oxidised copper or black anodised aluminium to improve thermal radiation;
the use of thin sheets (e.g. aluminium or copper at least 0.05 mm thick) in the manufacture of various heat sink components, instead of the cast components commonly used in prior art lamps;
the embedding of the LED circuit into the metallic substrate; and
the design is overall very thermally efficient and is the only one known to the present applicant to have exceeded 12 Watt input power in a lamp intended to be a direct replacement of an incandescent light bulb.

It is to be understood that not every embodiment of the invention needs to have each of these stated advantages.

References herein to LED lamp efficiencies are to be understood as referring to a thermal efficiency. One measure of thermal efficiency is the ratio of the maximum wattage handled by a lamp while the LEDs are below their maximum operating temperature.

Further advantages and improvements may very well be made to the present invention without deviating from its scope. Although the invention has been shown and described in what is conceived to be the most practical and preferred embodiment, it is recognized that departures may be made therefrom within the scope and spirit of the invention, which is not to be limited to the details disclosed herein but is to be accorded the full scope of the following claims so as to embrace any and all equivalent devices and apparatus.

In any claims that follow and in the summary of the invention, except where the context requires otherwise due to express language or necessary implication, the word “comprising” is used in the sense of “including”, i.e. the features specified may be associated with further features in various embodiments of the invention.

What is claimed is:

1. A light emitting diode (LED) lamp comprising one or more light emitting diodes (LEDs) mounted directly on a metallic base, wherein a circuit associated with the one or more LEDs is embedded in the metallic base.

2. A LED lamp as claimed in claim 1, wherein the metallic base is copper, aluminium, or a thermally conductive material that is plated with a metallic plating.

3. A LED lamp as claimed in claim 2, wherein the metallic plating is gold, silver, or tin.

4. A LED lamp as claimed in claim 3, wherein the metallic base is attached directly, by metal-to-metal contact, to a metallic heat sink.

5. A LED lamp as claimed in claim 4, wherein the one or more LEDs, the metallic base and the heat sink, are disposed inside a housing.

6. A LED lamp as claimed in claim 5, wherein the housing is made of glass, aluminium, steel, or a plastics material.

7. A LED lamp as claimed in claim 6, wherein the LED lamp has a longitudinal axis and the heat sink comprises longitudinally extending heat dissipating fins that are radially disposed about the longitudinal axis.

8. A LED lamp as claimed in claim 7, wherein the heat sink comprises a metallic sub-base which is attached to the metallic base, each fin projects outwardly away from the longitudinal axis, each fin is shaped substantially correspondingly with an internal shape of the housing, and each fin includes a laterally-extending foot that is attached to the metallic sub-base.

9. A LED lamp as claimed in claim 8, wherein the sub-base includes a central region, an outer annular region, and a plurality of radial tabs that are each integral with and extend from an outer perimeter of the outer annular region, the central region and the outer annular region are coaxial with the longitudinal axis, the metallic base is attached directly to the central region by metal-to-metal contact, and each tab is folded radially inward towards the longitudinal axis to respectively engage the foot of one of the fins between the tab and the outer annular region.

10. A LED lamp as claimed in claim 9, wherein each foot is engaged between the respective tab and the outer annular region of the sub-base by swaging, resistive welding, ultrasonic welding, soldering, spot welding, screwing or riveting.

11. A LED lamp as claimed in claim 10, wherein the housing includes an air inlet and an air outlet, and, in use of the LED lamp, the air inlet is located at a lower region of the housing, the air outlet is located at an upper region of the housing, and the heat sink is exposed to air which enters the housing through the air inlet to be heated by the heat sink, causing the air to rise inside the housing and be expelled from the housing through the air outlet, thereby drawing cooler air into the housing through the air inlet.

12. A LED lamp as claimed in claim 11, wherein the housing comprises a body portion which substantially surrounds the heat sink fins and an optically transparent or translucent portion, and the air inlet is defined by a gap between the body portion and the optically transparent or translucent portion.

13. A method of manufacturing a light emitting diode (LED) lamp comprising the steps of:
mounting one or more light emitting diodes (LEDs) directly on a metallic base; and
embedding a circuit associated with the LED or LEDs in the metallic base.

14. A method as claimed in claim 13, wherein the metallic base is copper, aluminium, or a thermally conductive material plated with a metallic plating.

15. A method as claimed in claim 14, wherein the metallic plating is gold, silver, or tin.

16. A method as claimed in claim 15, further comprising the step of:
attaching the metallic base to a metallic heat sink by direct metal-to-metal contact.

17. A method as claimed in claim 16, further comprising the steps of:
providing the heat sink with a plurality of radially-disposed heat dissipating fins which extend outwardly away from a longitudinal axis of the LED lamp;
attaching the fins by direct metal-to-metal contact to a metallic sub-base;
attaching the metallic sub-base to the metallic base; and
housing the fins, the metallic sub-base and the metallic base inside a housing.

18. A method as claimed in claim 17, wherein the step of attaching the fins by direct metal-to-metal contact to the metallic sub-base is performed by swaging, resistive welding, ultrasonic welding, soldering or spot welding, or by use of one or more fasteners.

19. A method as claimed in claim 18, wherein the step of attaching the metallic sub-base to the metallic base, is performed by swaging, resistive welding, ultrasonic welding, soldering or spot welding, or by use of one or more fasteners.

20. A method as claimed in claim 19, wherein the step of mounting the one or more LEDs directly on the metallic base is performed by a soldering process or by using an electrically-conductive adhesive or a thermally-conductive adhesive epoxy.
